(19) United States
(12) Patent Application Publication
(10) Pub. No.: US 2017/0137929 A1
(43) Pub. Date: May 18, 2017

(54) VACUUM EVAPORATION DEVICE

(71) Applicants: BOE TECHNOLOGY GROUP CO., LTD., Beijing (CN); ORDOS YUANSHENG OPTOELECTRONICS CO., LTD., Inner Mongolia (CN)

(72) Inventor: Haidong WU, Beijing (CN)

(21) Appl. No.: 14/435,726

(22) PCT Filed: Jul. 11, 2014
(86) PCT No.: PCT/CN2014/082054

§ 371 Date: Dec. 19, 2016

(30) Foreign Application Priority Data
Apr. 17, 2014 (CN) 201410155556.8

(51) Int. Cl. C23C 14/24; C23C 14/54; C23C 14/50

(52) U.S. Cl. CPC C23C 14/243; C23C 14/50; C23C 14/542

(57) ABSTRACT

The invention discloses a vacuum evaporation device, and relates to the technical field of vacuum evaporation. The utilization rate of an organic material in a vacuum evaporation process can be improved. The vacuum evaporation device comprises an evaporation chamber and an evaporation source arranged in the evaporation chamber, and further comprises a plurality of substrates arranged in the evaporation chamber, the plurality of substrates being positioned at an opened side of the evaporation source. A first spherical surface is formed by using an opening of the evaporation source as a spherical center, and each of the plurality of substrates is tangent to the first spherical surface.

### FIELD OF THE INVENTION

The present invention relates to the technical field of vacuum evaporation, and in particular to a vacuum evaporation device.

### BACKGROUND ART

A process in which a substance for a precursor of a film is disposed in vacuum for evaporation or sublimation and plated onto a substrate is called vacuum evaporation or vacuum coating. The vacuum coating process is largely applied in the manufacture of devices. E.g., a hole injection layer, a hole transport layer, a light-emitting layer or an electron transport layer of an organic light-emitting diode (OLED for short) is formed by vacuum evaporation processes. As shown in FIG. 1, a vacuum evaporation device comprises an evaporation chamber 3 which is provided with an evaporation source 4 and a substrate 1. The substrate 1 is located right above the evaporation source 4. The evaporation chamber 3 is provided in its wall with a vacuum aspirating hole 2 which is connected to a vacuum pump (not shown) outside the evaporation chamber 3. In the process of vacuum evaporation, the evaporation source 4 evaporates molecules of a gasified organic material towards the substrate 1, and the vacuum pump keeps vacuumizing the evaporation chamber 3 to maintain a vacuum environment therein such that the molecules of the gasified organic material fly towards the substrate 1 and form a film thereon. The direction indicated by arrows in the figure indicates a flow direction of the organic material molecules. However, while the organic material is evaporated on the substrate 1, much of it is evaporated on the wall of the evaporation chamber 3. As a result the organic material is largely wasted and the utilization rate of the organic material is low.

### SUMMARY

Embodiments of the present invention provide a vacuum evaporation device, which is capable of improving the utilization rate of an organic material during vacuum evaporation.

To solve the above technical problem, embodiments of the present invention adopt the following technical solutions.

A vacuum evaporation device is provided, comprising:

an evaporation chamber and an evaporation source arranged in the evaporation chamber, further comprising: a plurality of substrates arranged in the evaporation chamber, said plurality of substrates being positioned at an opened side of the evaporation source,

wherein a first spherical surface is formed by using an opening of the evaporation source as a spherical center, and each of the plurality of substrates is tangent to the first spherical surface.

Specifically, the opening of the evaporation source is provided with a hemispherical mask in which a plurality of evaporation holes are provided.

Specifically, each of the evaporation holes in the hemispherical mask is aligned with each of the substrates.

Furthermore, the substrates include a first substrate and a plurality of second substrates surrounding the first substrate,

the evaporation holes in the hemispherical mask include a first evaporation hole aligned with the first substrate and a plurality of evaporation holes arranged to surround the first evaporation hole, and

the evaporation source is arranged on a rotary device, which is configured to actuate the evaporation source to rotate at a uniform velocity with a line connecting the first substrate and the first evaporation hole as an axis.

Specifically, the evaporation chamber is provided in its wall with a plurality of vacuum aspirating holes, each of which corresponds to each of the substrates respectively.

Specifically, the vacuum evaporation device further comprises: a crystal oscillation sheet and a reference crystal oscillation sheet which are arranged in the evaporation chamber,

wherein the reference crystal oscillation sheet is provided with a baffle on a side facing the evaporation source.

Specifically, the vacuum evaporation device further comprises:

a film thickness detection unit which is connected with the crystal oscillation sheet and the reference crystal oscillation sheet, and which is configured to determine a thickness of a coating in accordance with a difference between the resonance frequency of the crystal oscillation sheet and that of the reference crystal oscillation sheet.

Furthermore, the evaporation source is a crucible or an evaporation boat.

Specifically, the substrates include five substrates.

The vacuum evaporation device according to the present invention is provided with a plurality of substrates, each of which is tangent to the first spherical surface formed with the opening of the evaporation source as a spherical center. As a result, each substrate obtains the organic material at the same velocity during evaporation, and thereby the evaporation process is performed on multiple substrates simultaneously through the same evaporation source, which improves the utilization rate of the organic material. Besides, the multiple substrates play the role of shielding to a certain extent, thus reducing the area of the wall of the evaporation chamber facing the evaporation source as well as the amount of organic material evaporated on the wall of the evaporation chamber. Consequently the waste of the organic material is cut down and the utilization rate of the organic material is further improved.

### BRIEF DESCRIPTION OF DRAWINGS

In order to explain more clearly the techncial sotluions in the embodiments of the present invention or in the prior art, the figures to be used in the descripstion of the embodiments or the prior art shall be briefly introduced as follows. Obviously, the figures in the following description are only some embodiments of the presnet invetnion.

FIG. 1 is a structural view of a vacuum evaporation device in the prior art;

FIG. 2 is a structural view of a vacuum evaporation device according to an embodiment of the present invention;

FIG. 3 is a schematic view for illustrating positional relations between an evaporation source and a pluraltiy of substrates in the vacuum evaporation device of FIG. 2;

FIG. 4 is a structural view of an evaporation source for the vacuum evaporation device of FIG. 2;

FIG. 5 is a top view of a hemispherical mask in FIG. 4;

FIG. 6 is a structural view of evaporation holes in the hemispherical mask of FIG. 5;

FIG. 7 is a top view of the vacuum evaporation device of FIG. 2;

FIG. 8 is a structural view of a further evaporation source in the vacuum device of FIG. 2; and

FIG. 9 is a top view of a hemispherical mask in FIG. 8.

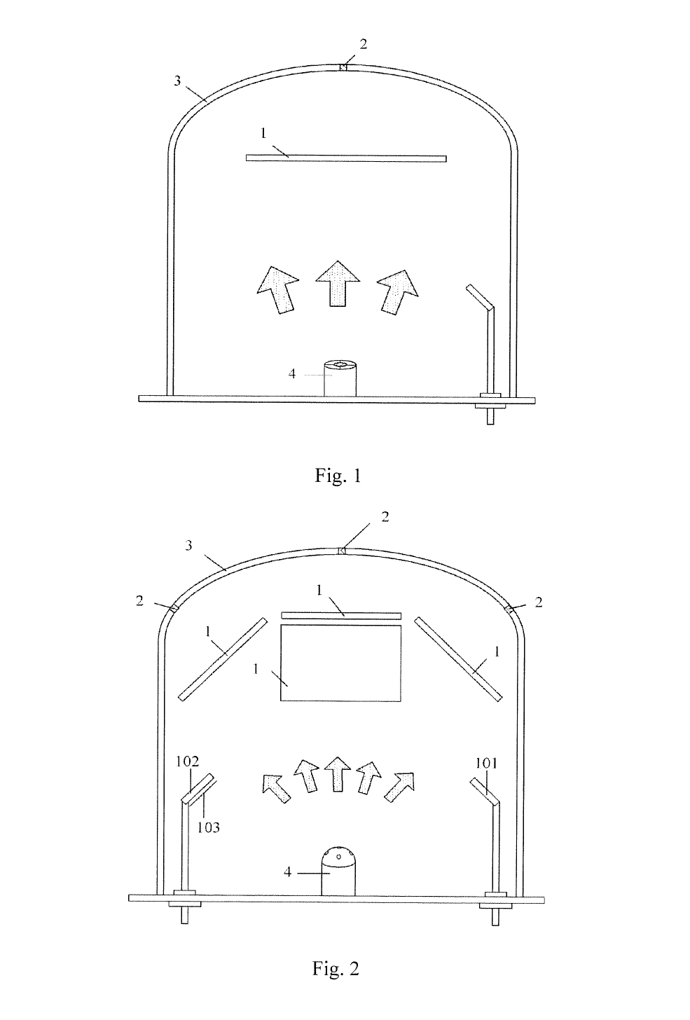

### DETAILED DESCRIPTION OF EMBODIMENTS

The technical solutions in the embodiments of the present invention shall be described clearly and completely in the follow text with reference to the figures in the embodiments of the present invention. Apparently, the described embodiments are only a part of the embodiments of the present invention, rather than all of them. Based on the embodiments of the present invention, all other embodiments obtained by the person having ordinary skills in the art without any inventive efforts shall fall within the protection scope of the present invention.

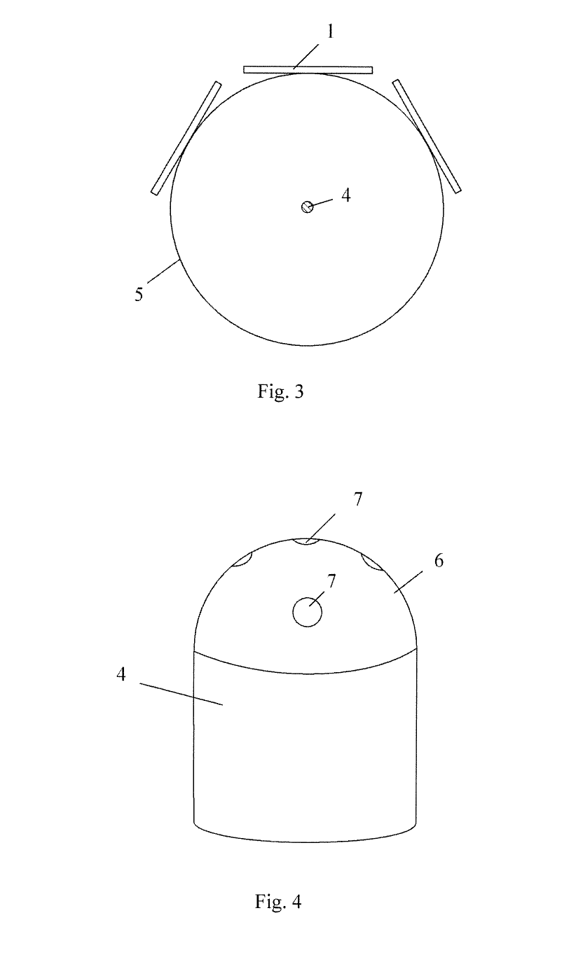

As shown in FIG. 2, according to an embodiment of the present invention a vacuum evaporation device is provided, which comprises an evaporation chamber 3 and an evaporation source 4 arranged in the evaporation chamber 3. The vacuum evaporation device further comprises multiple substrates 1 arranged in the evaporation chamber 3, said multiple substrates 1 being positioned at an opened side of the evaporation source 4. The substrates 1 can be for instance glass substrates. As shown in FIG. 3 (where only a part of the substrates are shown), a first spherical surface 5 is formed by using an opening of the evaporation source 4 as a spherical center, and all of the substrates are tangent to the first spherical surface 5. In the process of vacuum evaporation, organic material molecules diffuse continuously with the opening of the evaporation source 4 as a spherical center, so that each differential surface that is approximately planar on the first spherical surface 5 obtains the same amount of organic material molecules per unit time. The direction indicated by arrows in FIG. 2 indicates a flow direction of the organic material molecules. Multiple substrates 1 are tangent to the first spherical surface 5 such that they have the same evaporation effect. In this way, once the evaporation process is complete, the film of organic material evaporated on each substrate has the same thickness.

The vacuum evaporation device in embodiments of the present invention is provided with multiple substrates, each of which is tangent to the first spherical surface formed by using the opening of the evaporation source as a spherical center, such that each substrate obtains the organic material at the same velocity during evaporation, and thereby the evaporation process is performed on multiple substrates simultaneously through the same evaporation source, which improves the utilization rate of the organic material. Besides, the multiple substrates play the role of shielding to a certain extent, thus reducing the area of the wall of the evaporation chamber facing the evaporation source as well as the amount of organic material evaporated on the wall of the evaporation chamber. Consequently the waste of the organic material is cut down and the utilization rate of the organic material is further improved.

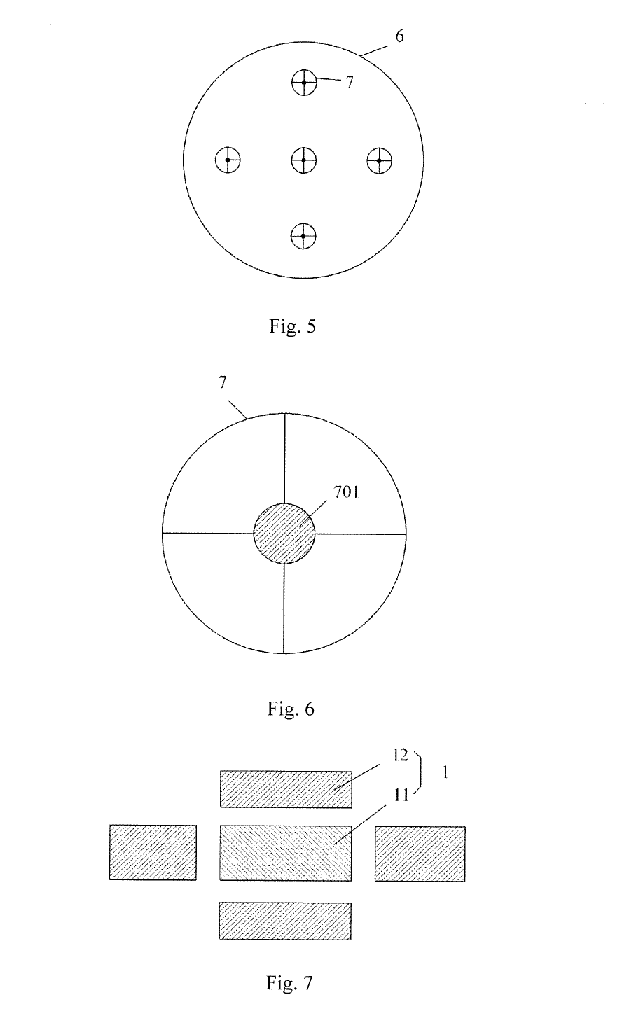

Specifically, as shown in FIGS. 4 and 5, a hemispherical mask 6 is provided at an opening of the evaporation source 4, and a plurality of evaporation holes 7 are provided in the hemispherical mask 6. Each evaporation hole 7 in the hemispherical mask 6 is aligned with each substrate 1. In this embodiment, the hemispherical mask 6 with evaporation holes 7 is provided at the opening of the evaporation source 4, and the other parts of the hemispherical mask are closed. During evaporation, organic material molecules diffuse from the plurality of evaporation holes 7 of the hemispherical mask 6 to each substrate 1 with the opening of the evaporation source 4 as a spherical center, enabling a better evaporation effect than the case in which the opening of the evaporation source 4 is used as a spot evaporation source. As shown in FIG. 6, a shielding part 701 surrounded by an opening area of the evaporation hole 7 is arranged at the center of the evaporation hole 7. The shielding part 701 is adjustable in size so as to change the size of the opening area and adjust the evaporation speed of the evaporation hole 7 during evaporation.

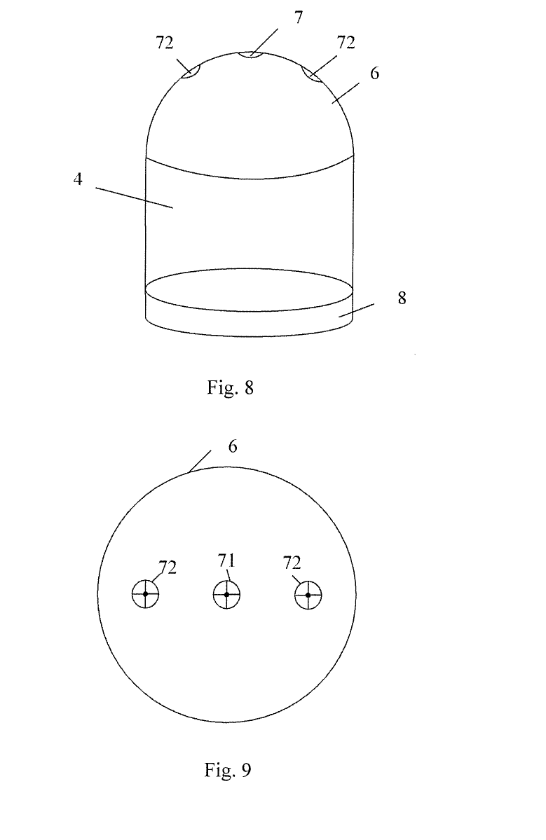

Optionally, as shown in FIG. 7, the substrates 1 include a first substrate 11 and a plurality of second substrates 12 surrounding the first substrate 11. As shown in FIGS. 8 and 9, the evaporation holes 7 in the hemispherical mask 6 include a first evaporation hole 71 aligned with the first substrate 11 and a plurality of evaporation holes 72 surrounding the first evaporation hole 71. The evaporation source 4 is arranged on a rotary device 8 which is configured to actuate the evaporation source 4 to rotate at a uniform velocity with a line connecting the first substrate 11 and the first evaporation hole 71 as an axis. During evaporation, while the evaporation source 4 evaporates the organic material onto the substrates 1, the evaporation source 4 rotates at a uniform velocity such that the organic material diffusing from the plurality of second evaporation holes 72 to the plurality of second substrates 12 is evenly distributed. By adjusting the size of the first evaporation hole 71, the first substrate 11 and the second substrates 12 can obtain the organic material at the same velocity. Moreover, since the plurality of second evaporation holes 72 can rotate around the first evaporation hole 71, it is unnecessary to arrange the second evaporation holes 72 to correspond respectively to each second substrate 12. For example, by arranging only two second evaporation holes 72, it is sufficient to evaporate four second substrates 12 simultaneously. Thus, the arrangement of the evaporation holes is made easier.

Specifically, as shown in FIG. 2, the evaporation chamber 3 is provided in its wall with a plurality of vacuum aspirating holes 2. Each of the vacuum aspirating holes corresponds to each of the substrates 1 respectively, and for example is aligned with the center of each substrate 1. During vacuum evaporation, the vacuum aspirating holes 2 are connected with a vacuum pump which is aranged outside the evaporation chamber 3 and works continuously to maintain a vacuum state in the evaporation chamber. The aspiration of the vacuum pump through the vacuum aspirating holes 2 will also change the vapor pressure and the concentration of organic vapor molecules at the substrates 1. In order to have the same vapor pressure and the same concentration of organic vapor molecules at each substrate 1, vacuum aspirating holes 2 are arranged in the wall of the evaporation chamber 3 at a position corresponding to each substrate 1. The arrangement of vacuum aspirating holes enables each substrate to be in the same vacuum state and the films evaporated on each substrate in the same batch of evaporation process to have the same thickness.

Furthermore, as shown in FIG. 2, the vacuum evaporation device further comprises a crystal oscillation sheet 101 and a reference crystal oscillation sheet 102 arranged in the evaporation chamber 3. The reference crystal oscillation sheet 102 is provided with a baffle 103 on a side facing the evaporation source 4. The vacuum evaporation device further comprises a film thickness detection unit (not shown in the figure) connected with the crystal oscillation sheet 101 and the reference crystal oscillation sheet 102 respectively. The film thickness detection unit is configured to determine a thickness of a coating in accordance with a difference between the resonance frequency of the crystal oscillation sheet 101 and that of the reference crystal oscillation sheet 102. There is a corresponding relation between the thickness of the film attached to the crystal oscillation sheet and the resonance frequency of the crystal oscillation sheet, so that it is possible to obtain the changes in the thickness of the film attached to the crystal oscillation sheet by measuring the variation of the resonance frequency of the crystal oscillation sheet. However, the environment of the crystal oscillation sheet may be changed during evaporation. For instance, changes in the temperature may have some influence on the resonance frequency of the crystal oscillation sheet. Therefore, changes in the environmental make the thickness of the coating detected by the crystal oscillation sheet inaccurate. The reference crystal oscillation sheet 102 is provided with a baffle 103 which prevents the organic material from being evaporated on the reference crystal oscillation sheet 102 during vacuum evaporation. The environmental changes inside the evaporation chamber 3 have the same influence on the resonance frequency of the crystal oscillation sheet 101 and that of the reference crystal oscillation sheet 102, and the thickness of the coating is obtained from a difference between the resonance frequency of the crystal oscillation sheet 101 and that of the reference crystal oscillation sheet 102. This can reduce, to some extent, the influence of the environmental changes inside the evaporation chamber during evaporation on the measurement of film thickness of the vacuum coating, thereby obtaining a more accurate thickness of the coating.

Furthermore, the evaporation source can be a crucible or an evaporation boat.

Specifically, the substrates can include five substrates. In the process of manufacturing an OLED display device, both the space of the evaporation chamber and the size of the substrates of the vacuum evaporation device have certain specifications, such that the vacuum evaporation device can achieve an optimal effect when five substrates are arranged. The substrates are not limited to five substrates.

The vacuum evaporation device in the embodiments of the present invention is provided with multiple substrates, each of which is tangent to the first spherical surface formed by using an opening of the evaporation source as the spherical center, such that each substrate obtains the organic material at the same velocity during evaporation, and thereby the evaporation process is performed on multiple substrates simultaneously through the same evaporation source. This improves the utilization rate of the organic material. Besides, the multiple substrates have a certain shielding function, thus reducing the area of the wall of the evaporation chamber facing the evaporation source as well as the amount of organic material evaporated on the wall of the evaporation chamber. Consequently the waste of the organic material is cut down and the utilization rate of the organic material is further improved. With the arrangement of a hemispherical mask at the opening of the evaporation source and a plurality of evaporation holes in the hemispherical mask, organic material molecules diffuse from the plurality of evaporation holes in the hemispherical mask with the opening of the evaporation source as a spherical center toward each substrate, and this can make the effect better when the opening of the evaporation source is used as a spot evaporation source. The arrangement of vacuum aspirating holes enables each substrate to be in the same vacuum state and the films evaporated on multiple substrates in the same batch of evaporation process to have the same thickness. By arranging a crystal oscillation sheet and a reference crystal oscillation sheet, the influence of the environmental changes inside the evaporation chamber during evaporation on the measurement of film thickness of the vacuum coating can be reduced to some extent, and thereby a more accurate thickness of the coating can be determined.

The above contents are only specific embodiments of the present invention, which cannot limit the protection scope of the present invention. Modifications or substitutions easily conceivable for any one who is familiar with the art within the technical disclosure of the present invention shall be considered as falling within the protection scope of the present invention. Therefore, the protection scope of the present invention should be subject to the protection scope of the claims.

1. A vacuum evaporation device, comprising an evaporation chamber and an evaporation source arranged in the evaporation chamber, and comprising:
a plurality of substrates arranged in the evaporation chamber, said plurality of substrates being positioned at an opened side of the evaporation source,
wherein a first spherical surface is formed by using an opening of the evaporation source as a spherical center, and each of the plurality of substrates is tangent to the first spherical surface.

2. The vacuum evaporation device according to claim 1, wherein the opening of the evaporation source is provided with a hemispherical mask in which a plurality of evaporation holes are provided.

3. The vacuum evaporation device according to claim 2, wherein each of the evaporation holes in the hemispherical mask is aligned with each of the plurality of substrates.

4. The vacuum evaporation device according to claim 2, wherein the plurality of substrates include a first substrate and a plurality of second substrates surrounding the first substrate;
wherein the plurality of evaporation holes in the hemispherical mask include a first evaporation hole aligned with the first substrate and a plurality of evaporation holes surrounding the first evaporation hole; and
wherein the evaporation source is arranged on a rotary device, which is configured to actuate the evaporation source to rotate at a uniform velocity with a line connecting the first substrate and the first evaporation hole as an axis.

5. The vacuum evaporation device according to claim 1, wherein the evaporation chamber is provided in its wall with a plurality of vacuum aspirating holes, each of which corresponds to each of the plurality of substrates respectively.

6. The vacuum evaporation device according to claim 1, further comprising:
a crystal oscillation sheet and a reference crystal oscillation sheet which are arranged in the evaporation chamber,
wherein the reference crystal oscillation sheet is provided with a baffle on a side facing the evaporation source.

7. The vacuum evaporation device according to claim 6, further comprising:
a film thickness detection unit which is connected with the crystal oscillation sheet and the reference crystal oscillation sheet, and which is configured to determine a thickness of a coating in accordance with a difference between the resonance frequency of the crystal oscillation sheet and that of the reference crystal oscillation sheet.

8. The vacuum evaporation device according to claim 1, wherein the evaporation source is a crucible or an evaporation boat.

9. The vacuum evaporation device according to claim 1, wherein the plurality of substrates include five substrates.

10. The vacuum evaporation device according to claim 2, wherein each of the evaporation holes is provided at its center with a shielding part with an adjustable size.

11. The vacuum evaporation device according to claim 2, further comprising:
a crystal oscillation sheet and a reference crystal oscillation sheet which are arranged in the evaporation chamber,
wherein the reference crystal oscillation sheet is provided with a baffle on a side facing the evaporation source.

12. The vacuum evaporation device according to claim 3, further comprising:
a crystal oscillation sheet and a reference crystal oscillation sheet which are arranged in the evaporation chamber,
wherein the reference crystal oscillation sheet is provided with a baffle on a side facing the evaporation source.

13. The vacuum evaporation device according to claim 4, further comprising:
a crystal oscillation sheet and a reference crystal oscillation sheet which are arranged in the evaporation chamber,
wherein the reference crystal oscillation sheet is provided with a baffle on a side facing the evaporation source.

14. The vacuum evaporation device according to claim 5, further comprising:
a crystal oscillation sheet and a reference crystal oscillation sheet which are arranged in the evaporation chamber,
wherein the reference crystal oscillation sheet is provided with a baffle on a side facing the evaporation source.

15. The vacuum evaporation device according to claim 11, further comprising:
a film thickness detection unit which is connected with the crystal oscillation sheet and the reference crystal oscillation sheet, and which is configured to determine a thickness of a coating in accordance with a difference between the resonance frequency of the crystal oscillation sheet and that of the reference crystal oscillation sheet.

16. The vacuum evaporation device according to claim 12, further comprising:
a film thickness detection unit which is connected with the crystal oscillation sheet and the reference crystal oscillation sheet, and which is configured to determine a thickness of a coating in accordance with a difference between the resonance frequency of the crystal oscillation sheet and that of the reference crystal oscillation sheet.

17. The vacuum evaporation device according to claim 13, further comprising:
a film thickness detection unit which is connected with the crystal oscillation sheet and the reference crystal oscillation sheet, and which is configured to determine a thickness of a coating in accordance with a difference between the resonance frequency of the crystal oscillation sheet and that of the reference crystal oscillation sheet.

18. The vacuum evaporation device according to claim 14, further comprising:
a film thickness detection unit which is connected with the crystal oscillation sheet and the reference crystal oscillation sheet, and which is configured to determine a thickness of a coating in accordance with a difference between the resonance frequency of the crystal oscillation sheet and that of the reference crystal oscillation sheet.

19. The vacuum evaporation device according to claim 3, wherein each of the evaporation holes is provided at its center with a shielding part with an adjustable size.

20. The vacuum evaporation device according to claim 4, wherein each of the evaporation holes is provided at its center with a shielding part with an adjustable size.
